(19) United States
(12) Patent Application Publication
(10) Pub. No.: US 2026/0191063 A1
(43) Pub. Date: Jul. 2, 2026

(54) PARTIAL LINERS FOR THROUGH-VIAS IN SEMICONDUCTOR PACKAGE SUBSTRATES

(71) Applicant: Intel Corporation, Santa Clara, CA (US)

(72) Inventors: Joshua STACEY, Chandler, AZ (US); Mahdi MOHAMMADIGHALENI, Phoenix, AZ (US); Mitchell PAGE, Mesa, AZ (US); Jacob SCHICHTEL, Chandler, AZ (US); Wei LI, Chandler, AZ (US); Bai NIE, Chandler, AZ (US); Thomas HEATON, Gilbert, AZ (US); Dilan SENEVIRATNE, Phoenix, AZ (US)

(21) Appl. No.: 19/003,379

(22) Filed: Dec. 27, 2024

(51) Int. Cl. H01L 23/498; H01L 21/48; H01L 23/15; H01L 23/538

(52) U.S. Cl. CPC H10W 70/69; H10W 70/05; H10W 70/095; H10W 70/60; H10W 70/611; H10W 70/685; H10W 70/692

(57) ABSTRACT

Semiconductor package substrates comprising solid amorphous glass layers are provided. The solid amorphous glass layers can have through-glass vias (TGVs) that include a layer of material that partially coats the walls of the vias. The partial coating can be on end regions of the through vias. Assemblies comprising these semiconductor package substrates and methods of manufacturing these semiconductor package substrates are provided.

### FIELD

Descriptions are generally related to semiconductor manufacturing, and more particular descriptions are related to semiconductor packaging for semiconductor chips and to semiconductor package substrates having glass cores with through-vias.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Advanced packaging solutions, such as heterogeneous integration, can improve performance and functionality of semiconductor devices and systems. Heterogeneous integration integrates dissimilar semiconductor chips having different functions in one package using, for example, lateral or vertical connections. Additionally, dissimilar devices such as, for example, central processing units (CPUs), graphics processing units (GPUs), infrastructure processing units (IPUs), and other devices, can be integrated into one large device. It can be the case that the large integrated device is divided into smaller portions (chiplets) for manufacturing and then operably connected through a package substrate. Manufacturing these types of packages and others can be facilitated by using package substrates having glass cores. Glass substrate cores can provide lower cost, dimensional stability, and higher density interconnects than cores made of other materials. The brittleness of glass can, however, present manufacturing challenges that lead to yield losses.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIGS. 1A-1B illustrate conductive through glass vias for semiconductor package substrates.

FIG. 2 shows a semiconductor package substrate having conductive through glass vias.

FIG. 3 provides an assembly comprising a semiconductor package substrate having through glass vias.

FIGS. 4A-4D show methods for manufacturing a semiconductor package core comprising through-core vias.

FIG. 5 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or implementation. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative implementations. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain implementations require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Physical operations can be performed by semiconductor processing and/or testing equipment, including computer systems that run semiconductor process protocols and operate aspects of process equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, lithography, probing, material deposition (for example, chemical vapor deposition (CVD), atomic layer deposition (ALD), physical vapor deposition (PVD), electrodeposition, and/or sputtering), chemical mechanical planarization (CMP), and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass layers.

In further examples of a package substrate core, the substrate core is a glass core comprising one or more solid amorphous glass layers. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass core package substrate core comprises at least 23% silicon and at least 26% oxygen by weight. In further examples, the glass core package substrate core comprises at least 23% silicon, at least 26% oxygen, and at least 5% aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example the substrate core can be 10 mm by 10 mm up to 250 mm by 250 mm in two dimensions (or a length therebetween or a larger or smaller length), but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example.

Package substrates comprising a solid glass material layer and through-glass vias (TGV's) that comprise a metal, such as, for example, copper, can experience failures due at least partially to coefficient of thermal expansion (CTE) mismatches between the metal (e.g., copper) and the solid glass substrate. For example, a failure mode for solid glass substrates can involve crack formation in the glass substrate. CTE mismatches between TGV's and solid glass substrates can lead to failures during subsequent processing steps in which the package is heated. It was found that the location of the highest stress on a glass core can occur at the TGV opening for flush TGVs or at the Cu surface for recessed TGVs. Adding a compliant material between the Cu and glass can buffer stresses and prevent glass core degradation.

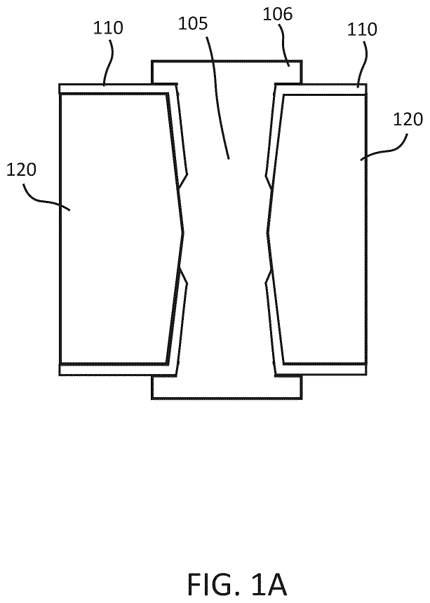

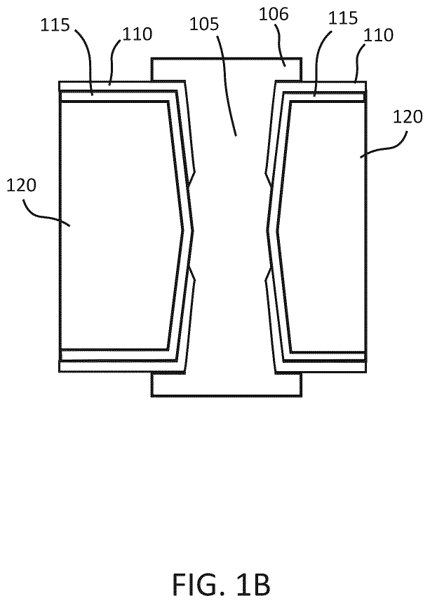

FIG. 1A -1B provide conductive through-core vias that can be used with glass cores in semiconductor package substrates. The through-core vias comprise a conductive region 105 and a conductive pad region 106. The conductive region 105 and conductive pad region 106 can comprise a metallic material, such as copper, aluminum, platinum, gold, or an alloy thereof. Other materials are possible, such as, for example, materials that are conductive metals. The glass core 120 can be any of the types of glass cores described herein. Other materials are also possible. The glass core 120 can be a solid amorphous glass layer. A solid amorphous glass layer can occupy a rectangular prism volume and a rectangular prism volume can be an approximate description of the shape in that corners can be rounded or chamfered and/or the thickness of the glass layer can be inconsistent. The conductive through-core vias can also comprise cap layers 110 that are on ends of the vias and partially extend into the through-core vias. The cap layers 110 can be between the glass core 120 and a conductive region 105/pad region 106. The cap layers 110 can be comprised of dielectric material having low modulus of elasticity and/or having solubility in a solvent. The cap layers 110 can be comprised of, for example, a filled or un-filled epoxy-based resin (filled, for example, with silica particles) material, a polyimide material, and/or a photoresist material. The cap layers in the via can have a thickness of between and including 500 nm and 20 μm.

The cap layers 110 can optionally comprise more than one layer that can be comprised of the same or different materials.

In FIG. 1B, the through-core via also includes a conformal layer 115 between the glass core '120 material and the conductive region. The conformal layer 115 can comprise one or more layers of, for example, a high modulus of elasticity material that is able to conform to the shape of the end of a via and surface of a package substrate. The conformal layer 115 can be, for example, a material such as, SiOₓ, SiₓO_{y}C_{z}W (where W can be H, F, nothing, or something else), siloxane, and/or SiNₓ.

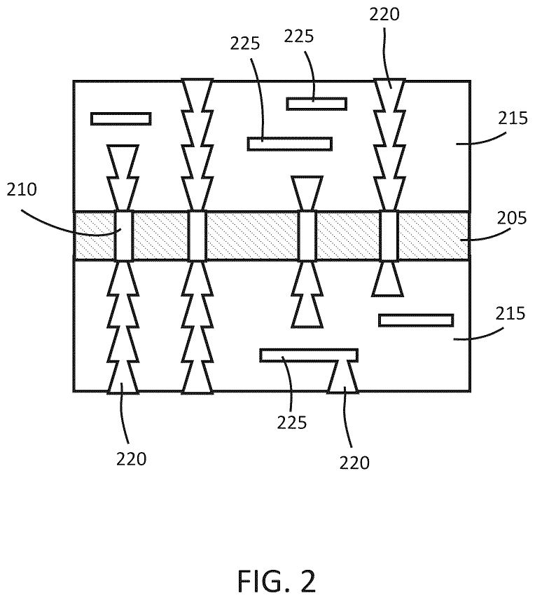

FIG. 2 illustrates an example of a package substrate having a glass core 205. The glass core 205 can comprise conductive through-core vias 210. The glass core 205 and through-core vias 210 can be, for example, any of the glass cores and conductive through-core vias of FIGS. 1A-1B . The package substrate additionally comprises a dielectric region 215. The dielectric region 215 can comprise layers (individual layers not shown) of dielectric material, such as, for example, build-up films, such as ABF. Further, the package substrate can comprise conductive vias 220 and conductive lines 225. The conductive vias 220 and conductive lines 225 can comprise a metallic material, such as, for example, copper. A typical package substrate can comprise a much larger number of through-core vias 210, conductive vias 220, and/or conductive lines 225 as well as having these features in different arrangements and locations.

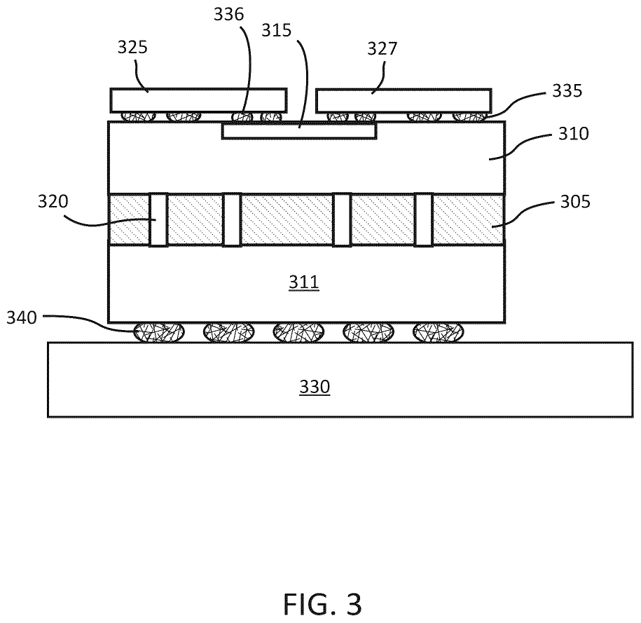

FIG. 3 shows a semiconductor device assembly that includes a package substrate having a glass core 305. The package substrate comprises a glass core 305, dielectric regions 310 and 311, and an optional interconnect bridge 315. The glass core 305 comprises conductive through-core vias 320. The glass core 305 and conductive through-core vias 320 can be any of the glass cores and conductive through-core vias of FIGS. 1A-1B . The interconnect bridge 315 can be any of the interconnect bridges described herein, such as an EMIB. The interconnect bridge 315 can be embedded, partially embedded, or on the package substrate (FIG. 3 illustrates an embedded option). A package substrate can comprise multiple instances of interconnect bridges 315. The dielectric regions 310 and 311 can be similar to the ones described with respect to FIG. 2, and can comprise layers (not shown) and conductive lines and vias (not shown). The semiconductor device assembly also includes semiconductor chips 325 and 327 and circuit board 330. Other numbers of semiconductor chips 325 and 327 are possible, such as just one semiconductor chip, three semiconductor chips, or more than three semiconductor chips. Semiconductor chips 325 and 327 can be operably connected to the package substrate through first level interconnects (FLIs) 335 and 336 that comprise conductive regions such as for example, solder, pins, pads, and/or pillars. The semiconductor package can be operably coupled to the circuit board 330 through conductive board interconnections 340 which can be, for example, solder, pins, pads, pillars, and/or sockets.

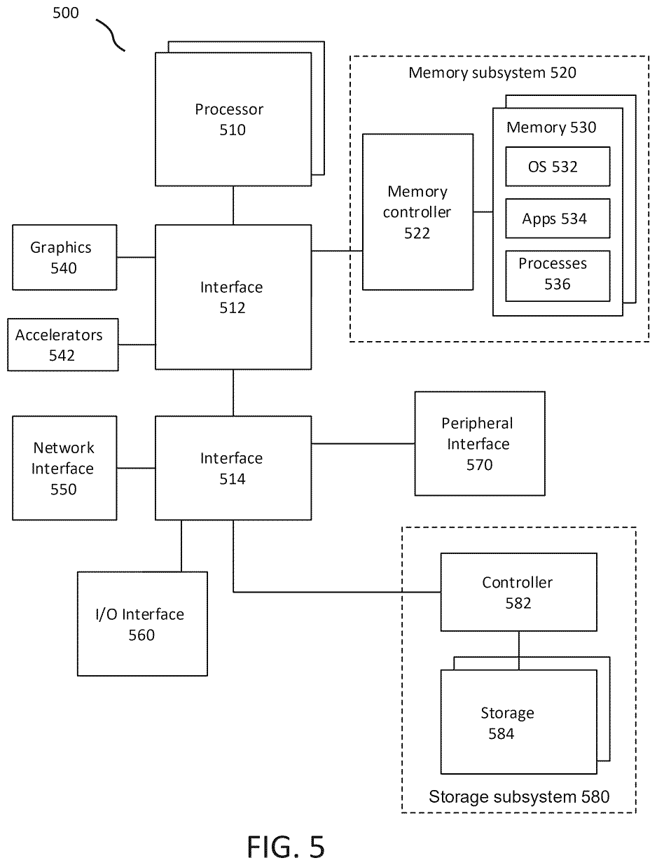

Semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 5. The semiconductor chip packages described herein generally can be part of various larger package structures and configurations and the foregoing examples are not meant to limit the types of assemblies that are possible.

The circuit board 330 can be, for example, a motherboard, a printed circuit board, a system board, a logic board, a main board, or a board (which can sometimes be used interchangeably). The circuit board 330 can include a power supply that can control the amount of current and/or voltage going to components of the circuit board 330, such as the amount of current and/or voltage supplied to the semiconductor chips 325 and 327. The circuit board 330 can also provide interconnections processors and other computing devices and memory, such as DRAM.

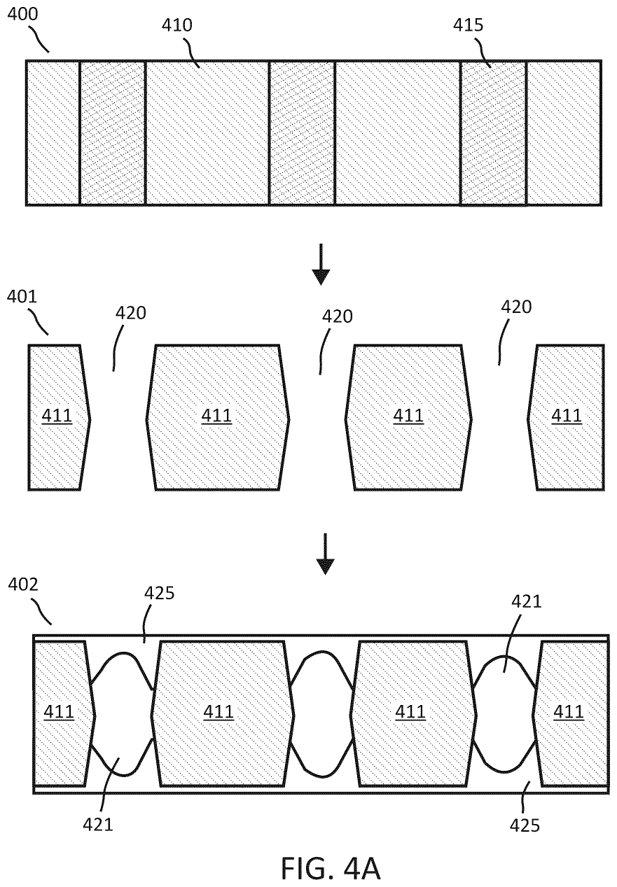

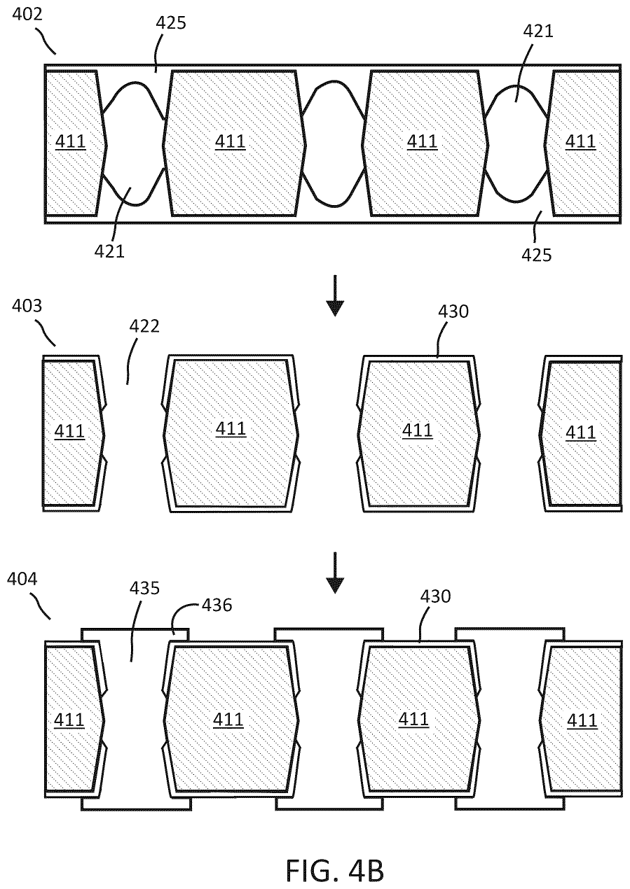

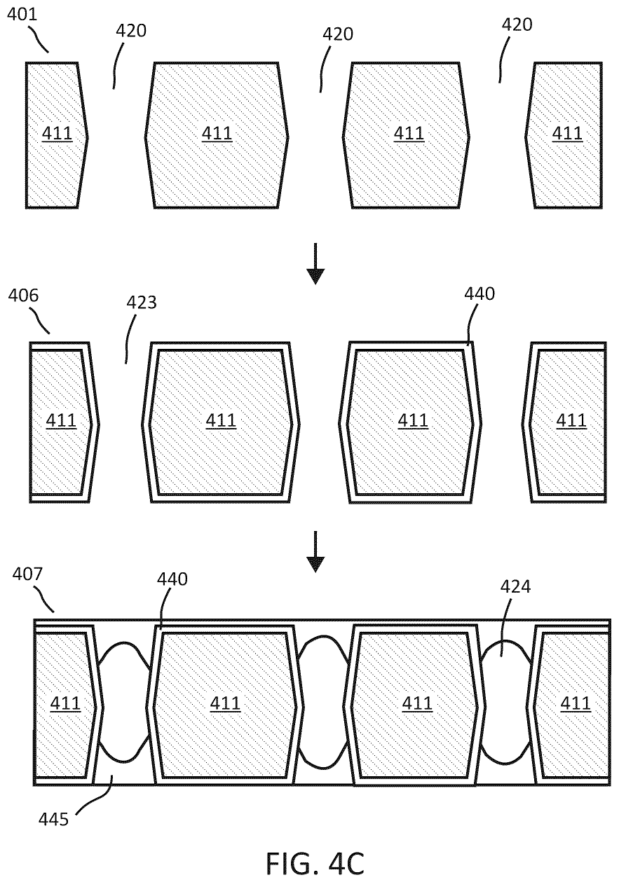

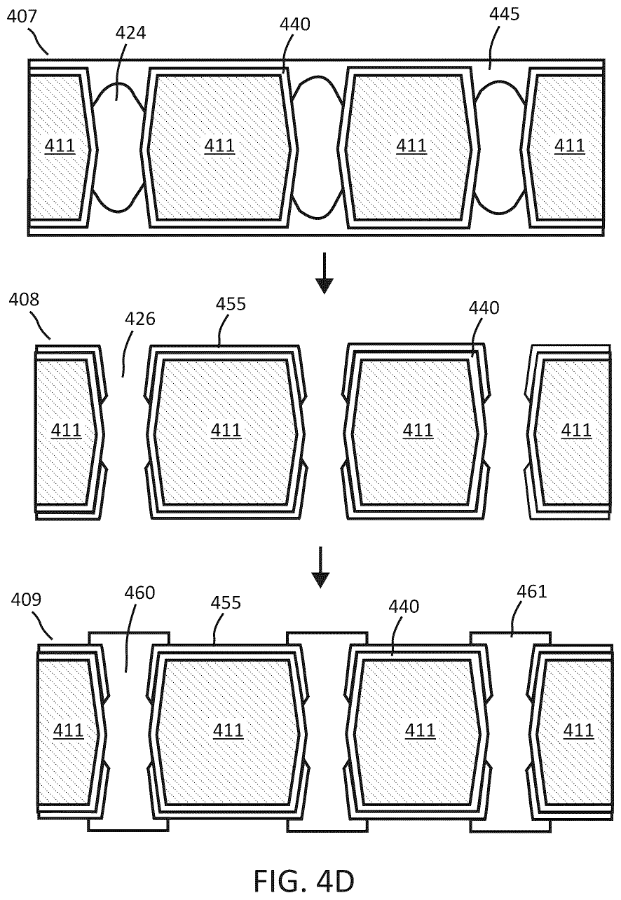

FIG. 4A-4B describe methods for forming conductive through vias in glass substrates. In FIG. 4A, partially-manufactured glass core 400 for a package substrate, includes a glass region 410 and laser-modified glass regions 415. The partially-manufactured glass core 400 can comprise any of the glass materials described herein and can be a solid layer or solid material having a prismatic shape. Laser-modified glass regions 415 can have been created through the application of laser light that predisposes the glass to etching. Etching the partially-manufactured glass core 400 produces a second partially-manufactured glass core 401 that comprises cavity vias 420 in a glass region 411. The etching process can be a liquid etching process.

Partially-manufactured glass core 402 can be built through a vacuum lamination process using a rubber and/or conformal press to apply cap layer 425. The lamination process leaves the TVGs partially plugged and a gas-filled via region 421. Two single sided lamination processes or a single two-sided lamination process can be used to create plugs on opposite ends of the TGVs. Selection of the thickness of the cap layer 425 material to be laminated can be used to determine the depth of plugging of the TGVs by the cap layer 425. Cap layer 425 material can be, for example, a filled or un-filled epoxy-based resin (filled, for example, with silica particles) material, a polyimide material, and/or a photoresist material.

In FIG. 4B, a laser drilling process or photolithographic process can be used to create partially-manufactured glass core 403. Partially-manufactured glass core 403 has through-glass vias 422 that include cap layers 430. The laser drilling or photolithographic process can remove the plug and leave a cap layer 430 that partially covers the walls of the through-glass vias 422 on the ends of the through-glass via 422. For a photolithographic process that opens the through-glass via 422, the cap layer 425 can be comprised of a photoresist material. For a laser drilling process, the cap layer 425 can be comprised of a filled or un-filled epoxy-based resin material, a polyimide material, a photoresist material, and/or another low modulus polymeric material that is processable through vacuum lamination.

Conductive material is deposited into the cavity vias 422 of partially-manufactured glass core 403 to create conductive regions 435 and conductive pad regions 436 in glass core 404. The conductive regions 435 and/or 436 can comprise, for example, a metallic material, such as, copper, gold, aluminum, platinum, or an alloy thereof. A seed layer comprising a metallic material can be deposited by CVD, ALD, or PVD, and the bulk of the via filled with a conductive material region 435 and/or 436 by, for example, electrodeposition or electroplating process. Optionally, a seed layer can be used for an electrodeposition or electroplating process. A seed layer can comprise copper metal, for example, when the metallic material is copper.

In FIG. 4C, a partially-manufactured glass core 406 for a package substrate can be manufactured by depositing a conformal layer 440 onto partially-manufactured glass core 401. The conformal layer 440 coats the sides of the through-vias 423. The conformal layer 440 can be comprised of, for example, one or more layers of a material such as, SiOₓ, SiₓO_{y}C_{z}W (where W can be H, F, nothing, or something else), siloxane, and/or SiNₓ. and can be deposited by CVD, thermal CVD, PECVD (plasma enhanced chemical vapor deposition), SACVD (sub-atmospheric chemical vapor deposition), or iCVD (initiated CVD).

Partially-manufactured glass core 407 can be built through a vacuum lamination process using a rubber and/or conformal press to apply cap layer 445. The lamination process leaves the TVGs partially plugged and a gas-filled via region 424. Two single sided lamination processes or a single two-sided lamination process can be used to create plugs on opposite ends of the TGVs. Selection of the thickness of the cap layer 445 material to be laminated can be used to determine the depth of plugging of the TGVs by the cap layer 445. Cap layer 445 material can be, for example, a filled or un-filled epoxy-based resin (filled, for example, with silica particles) material, a polyimide material, and/or a photoresist material.

In FIG. 4D, a laser drilling process or photolithographic process can be used to create partially-manufactured glass core 408. Partially-manufactured glass core 408 has through-glass vias 426 that include cap layers 455. The laser drilling or photolithographic process can remove the plug and leave a cap layer 455 that partially covers the walls of the through-glass vias 426 on the ends of the through-glass via 426. For a photolithographic process that opens the through-glass via 424, the cap layer 445 can be comprised of a photoresist material. For a laser drilling process, the cap layer 445 can be comprised of a filled or un-filled epoxy-based resin (filled, for example, with silica particles) material, a polyimide material, and/or a photoresist material.

Conductive material is deposited into the cavity vias 426 of partially-manufactured glass core 408 to create conductive regions 460 and conductive pad regions 461 in glass core 409 for package substrates. The conductive regions 460 and/or 461 can comprise, for example, a metallic material, such as, copper, gold, aluminum, platinum, or an alloy thereof. A seed layer comprising a metallic material can be deposited by CVD, ALD, or PVD, and the bulk of the via filled with a conductive material region 460 and/or 461 by, for example, electrodeposition or electroplating process. Optionally, a seed layer can be used for an electrodeposition or electroplating process. A seed layer can comprise copper metal, for example, when the metallic material is copper.

Glass core 404 for a package substrate can be, for example, a glass core that comprises the through-vias of FIG. 1A. Glass core 409 for a package substrate can be, for example, a glass core that comprises the through-vias of FIG. 1B.

Although the shape of the conductive vias is shown as having walls that angle inward, the shape can also be closer to cylindrical. The angle of the side walls can be, for example, a 0-10 degree angle.

FIG. 5 depicts an example computing system 500. The computing system can be a system used for running equipment in a semiconductor fabrication plant. For example, instructions for operating semiconductor process tools, or for performing one or more aspects of the processes described in FIGS. 4A-4D can be stored and/or run on the computing system. A computing system 500 can include more, different, or fewer features than the ones described with respect to FIG. 5.

Computing system 500 includes processor 510, which provides processing, operation management, and execution of instructions for system 500. Processor 510 can include any type of microprocessor, CPU (central processing unit), GPU (graphics processing unit), processing core, or other processing hardware to provide processing for system 500, or a combination of processors or processing cores. Processor 510 controls the overall operation of system 500, and can be or include, one or more programmable general-purpose or special-purpose microprocessors, DSPs, programmable controllers, ASICs, programmable logic devices (PLDs), or the like, or a combination of such devices.

In one example, system 500 includes interface 512 coupled to processor 510, which can represent a higher speed interface or a high throughput interface for system components needing higher bandwidth connections, such as memory subsystem 520 or graphics interface components 540, and/or accelerators 542. Interface 512 represents an interface circuit, which can be a standalone component or integrated onto a processor die. Where present, graphics interface 540 interfaces to graphics components for providing a visual display to a user of system 500. In one example, the display can include a touchscreen display.

Accelerators 542 can be a fixed function or programmable offload engine that can be accessed or used by a processor 510. For example, an accelerator among accelerators 542 can provide data compression (DC) capability, cryptography services such as public key encryption (PKE), cipher, hash/authentication capabilities, decryption, or other capabilities or services. In some cases, accelerators 542 can be integrated into a CPU socket (e.g., a connector to a motherboard (or circuit board, printed circuit board, mainboard, system board, or logic board) that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 530 stores and hosts, among other things, operating system (OS) 532 that provides a software platform for execution of instructions in system 500, and stores and hosts applications 534 and processes 536. In one example, memory subsystem 520 includes memory controller 522, which is a memory controller to generate and issue commands to memory 530. The memory controller 522 can be a physical part of processor 510 or a physical part of interface 512. For example, memory controller 522 can be an integrated memory controller, integrated onto a circuit within processor 510.

System 500 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 500 includes interface 514, which can be coupled to interface 512. In one example, interface 514 represents an interface circuit, which can include standalone components and integrated circuitry. In one example, user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB, or other wired or wireless standards-based or proprietary interfaces. Network interface 550 can transmit data to a device that is in the same data center or rack or a remote device, which can include sending data stored in memory.

Some examples of network interface 550 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include additional types of hardware interfaces, such as, for example, interfaces to semiconductor fabrication equipment and/or electrostatic charge management devices.

In one example, system 500 includes storage subsystem 580. Storage subsystem 580 includes storage device(s) 584, which can be or include any conventional medium for storing data in a nonvolatile manner, such as one or more magnetic, solid state, and/or optical based disks. Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 512 or processor 510 or can include circuits or logic in both processor 510 and interface 514.

A power source (not depicted) provides power to the components of system 500. More specifically, power source typically interfaces to one or multiple power supplies in system 500 to provide power to the components of system 500.

Examples of systems may be implemented in various types of computing, smart phones, tablets, personal computers, and networking equipment, such as switches, routers, racks, and blade servers such as those employed in a data center and/or server farm environment.

A computer-readable medium on which instructions are stored in a non-transitory form, that when executed by a computer, can cause a system to perform any of the methods described herein and illustrated in the accompanying figures.

### EXAMPLES

A device can comprise: a substrate wherein the substrate comprises a solid amorphous glass layer; a first via in the solid amorphous glass layer wherein the first via has walls, wherein the walls have a first end and a second end, wherein the first via has a second layer of material, wherein the second layer of material partially covers the walls on the first end of the walls, wherein the first via also comprises a conductive material, wherein the second layer of material is between the solid amorphous glass layer and the conductive material, and wherein there is a region where the second layer is not between the solid amorphous glass layer and the conductive material; dielectric layers on a first side and a second side of the solid amorphous glass layer, wherein the first side of the solid amorphous glass layer is opposite the second side of the solid amorphous glass layer; and conductive lines and conductive second vias in the dielectric layers wherein a conductive second via of the conductive second vias is electrically connected to the first via. The second layer of material can comprise an epoxy material, a polyimide material, or a photoresist material. The second layer of material can also partially cover the walls on the second end of the walls. The first via can also comprise a third layer on the walls of the first via. The first via can also comprise a third layer that can comprise SiOₓ, SiₓO_{y}C_{z}W, siloxane, or SiNₓ. The solid amorphous glass layer can comprise aluminosilicate, borosilicate, alumino-borosilicate, silica, or fused silica. The solid amorphous glass layer can comprise Al₂O₃, B₂O₃, MgO, CaO, SrO, BaO, SnO₂, Na₂O, K₂O, SrO, P₂O₃, ZrO₂, Li₂O, Ti, or Zn. The conductive material can comprise copper metal.

An assembly can comprise: a substrate wherein the substrate comprises a solid amorphous glass layer; a via in the solid amorphous glass layer wherein the via has walls, wherein the walls have a first end and a second end, wherein the via has a second layer of material, wherein the second layer of material partially covers the walls on the first end of the of the walls, wherein the via also comprises a conductive material, wherein the second layer of material is between the solid amorphous glass layer and the conductive material, and wherein there is a region where the second layer is not between the solid amorphous glass layer and the conductive material; and a semiconductor die wherein the semiconductor die is electrically coupled to the via. The second layer of material can comprise an epoxy material, a polyimide material, or a photoresist material. The substrate can also comprise an interconnect bridge and the interconnect bridge can be electrically connected to the semiconductor die. The via can also comprise a third layer of material wherein the third layer of material can comprise SiOₓ, SiₓO_{y}C_{z}W, siloxane, or SiNₓ. The solid amorphous glass layer can comprise aluminum, boron, magnesium, calcium, barium, tin, sodium, potassium, strontium, phosphorus, zirconium, lithium, titanium, or zinc. The solid amorphous glass layer can comprise at least 23% silicon and at least 26% oxygen by weight. The assembly can also include a circuit board wherein the circuit board is electrically connected to the semiconductor die through the substrate.

A method can comprise: creating a through via in a glass substrate wherein the glass substrate comprises a solid amorphous glass layer; laminating a second layer of material on the glass substrate in a manner so that some of the second layer extends into the through via forming a plug in an end of the through via; forming a hole in the plug; and depositing copper metal into the through via. Creating a through via can comprise pretreating a region of the glass substrate with a laser and preferentially etching the region that was pretreated with the laser. Depositing copper metal can occur through an electrodeposition or electroplating process. The method can also include depositing a third layer of material into the through via wherein the second layer can comprise SiOₓ, SiₓO_{y}C_{z}W, siloxane, or SiNₓ. The second layer of material can comprise an epoxy material, a polyimide material, or a photoresist material.

Besides what is described herein, various modifications can be made to what is disclosed and implementations without departing from their scope. Therefore, the illustrations and examples herein should be construed in an illustrative, and not a restrictive sense.

What is claimed is:

1. A device comprising:
a substrate wherein the substrate comprises a solid amorphous glass layer;
a first via in the solid amorphous glass layer wherein the first via has walls, wherein the walls have a first end and a second end, wherein the first via has a second layer of material, wherein the second layer of material partially covers the walls on the first end of the walls, wherein the first via also comprises a conductive material, wherein the second layer of material is between the solid amorphous glass layer and the conductive material, and wherein there is a region where the second layer is not between the solid amorphous glass layer and the conductive material;
dielectric layers on a first side and a second side of the solid amorphous glass layer, wherein the first side of the solid amorphous glass layer is opposite the second side of the solid amorphous glass layer; and
conductive lines and conductive second vias in the dielectric layers wherein a conductive second via of the conductive second vias is electrically connected to the first via.

2. The device of claim 1 wherein the second layer of material is comprised of an epoxy material, a polyimide material, or a photoresist material.

3. The device of claim 1 wherein the second layer of material also partially covers the walls on the second end of the walls.

4. The device of claim 1 wherein the first via also comprises a third layer on the walls of the first via.

5. The device of claim 1 wherein the first via also comprises a third layer that is comprised of SiOₓ, SiₓO_{y}C_{z}W, siloxane, or SiNₓ.

6. The device of claim 1 wherein the solid amorphous glass layer comprises aluminosilicate, borosilicate, alumino-borosilicate, silica, or fused silica.

7. The device of claim 1 wherein the solid amorphous glass layer comprises Al₂O₃, B₂O₃, MgO, CaO, SrO, BaO, SnO₂, Na₂O, K₂O, SrO, P₂O₃, ZrO₂, Li₂O, Ti, or Zn.

8. The device of claim 1 wherein the conductive material is comprised of copper metal.

9. An assembly comprising:
a substrate wherein the substrate comprises a solid amorphous glass layer;
a via in the solid amorphous glass layer wherein the via has walls, wherein the walls have a first end and a second end, wherein the via has a second layer of material, wherein the second layer of material partially covers the walls on the first end of the of the walls, wherein the via also comprises a conductive material, wherein the second layer of material is between the solid amorphous glass layer and the conductive material, and wherein there is a region where the second layer is not between the solid amorphous glass layer and the conductive material; and
a semiconductor die wherein the semiconductor die is electrically coupled to the via.

10. The assembly of claim 9 wherein the second layer of material is comprised of an epoxy material, a polyimide material, or a photoresist material.

11. The assembly of claim 9 wherein the substrate also comprises an interconnect bridge and the interconnect bridge is electrically connected to the semiconductor die.

12. The assembly of claim 9 wherein the via also comprises a third layer of material wherein the third layer of material is comprised of SiOₓ, SiₓO_{y}C_{z}W, siloxane, or SiNₓ.

13. The assembly of claim 9 wherein the solid amorphous glass layer comprises aluminum, boron, magnesium, calcium, barium, tin, sodium, potassium, strontium, phosphorus, zirconium, lithium, titanium, or zinc.

14. The assembly of claim 9 wherein the solid amorphous glass layer comprises at least 23% silicon and at least 26% oxygen by weight.

15. The assembly of claim 9 also including a circuit board wherein the circuit board is electrically connected to the semiconductor die through the substrate.

16. A method comprising:
creating a through via in a glass substrate wherein the glass substrate comprises a solid amorphous glass layer;
laminating a second layer of material on the glass substrate in a manner so that some of the second layer extends into the through via forming a plug in an end of the through via;
forming a hole in the plug; and
and depositing copper metal into the through via.

17. The method of claim 16 wherein creating a through via comprises pretreating a region of the glass substrate with a laser and preferentially etching the region that was pretreated with the laser.

18. The method of claim 16 wherein depositing copper metal occurs through an electrodeposition or electroplating process.

19. The method of claim 16 also including depositing a third layer of material into the through via wherein the second layer is comprised of SiOₓ, SiₓO_{y}C_{z}W, siloxane, or SiNₓ.

20. The method of claim 16 wherein second layer of material is comprised of an epoxy material, a polyimide material, or a photoresist material.
